(19) United States
(12) Patent Application Publication
(10) Pub. No.: US 2012/0075033 A1
(43) Pub. Date: Mar. 29, 2012

(54) SINGLE MATCHING NETWORK FOR MATCHING MULTI-FREQUENCY AND METHOD OF CONSTRUCTURING THE SAME AND RADIO FREQUENCY POWER SOURCE SYSTEM USING THE SAME

(76) Inventors: Liang OUYANG, Shanghai (CN); Lei Liu, Anhui (CN); Xueming Qian, Shanghai (CN); Jinyuan Chen, Union City, CA (US)

(21) Appl. No.: 13/239,316

(22) Filed: Sep. 21, 2011

(30) Foreign Application Priority Data
Sep. 29, 2010 (CN) 201010296641.8

(51) Int. Cl. H03H 7/38; H01R 43/00

(52) U.S. Cl. 333/32; 29/825

(57) ABSTRACT

A single matching network is adapted to input at least two frequencies, which is used to selectively provide an RF power match at any one of the at least two frequencies to a plasma load, and the single matching network includes an input terminal connected to a multi-frequency input and an output terminal connected to the plasma load. A capacitor and an inductor connected in series with each other are provided between the input terminal and the output terminal to form a branch, the capacitance value of the capacitor is C₀, and the inductance value of the inductor is Lₒ, wherein, the capacitance value C₀ and the inductance value L₀ satisfy the following relations:

jω₁L₀+1/jω₁C₀=jy1

jω₂L₀+1/jω₂C₀=jy2

wherein, ω₁=2πf1, ω₂=2πf2, the f1 and f2 are respectively the two frequencies, y1 is the impedance required for the branch when achieving a matching state at frequency f1, and y2 is the impedance required for the branch when achieving a matching state at frequency f2.

### RELATED APPLICATIONS

This application claims priority from Chinese Patent Application Serial No. 201010296641.8, which was filed on Sep. 29, 2010, the entire disclosure of which is incorporated herein by reference.

### BACKGROUND

1. Field

The invention relates to Radio Frequency (RF) power source and matching network of a plasma process chamber, and particularly to a matching network capable of realizing the selective application of multi-frequency RF powers, a method of constructing the same and an RF power source system using the same.

2. Related Art

Plasma chambers utilizing dual or multiple RF frequencies are known in the art. Generally, a plasma chamber of dual frequencies receives RF bias power having frequency below about 15 MHz, and an RF source power at higher frequency, normally 27-200 MHz. In this context, RF bias generally refers to the RF power which is used to control the ion energy and ion energy distribution. On the other hand, RF source power generally refers to RF power which is used to control the plasma ion dissociation or plasma density. For some specific examples, it has been known to operate etch plasma chambers at, e.g., bias of 100 KHz, 2 MHz, 2.2 MHz or 13.56 MHz, and source at 13.56 MHz, 27 MHz, 60 MHz, 100 MHz, and higher.

Recently it has been proposed to operate a plasma chamber at one bias frequency and two source frequencies. For example, it has been proposed to operate a plasma etch chamber at bias frequency of 2 MHz and two source frequencies of 27 MHz and 60 MHz. In this manner, the dissociation of various ion species can be controlled using the two source RF frequencies. Regardless of the configurations, in the prior art each frequency is provided by an individual RF power supplier and each individual power supplier is coupled to an individual matching network.

FIG. 1 is a schematic illustration of a prior art multiple frequency plasma chamber arrangement, having one bias RF power and two source RF power generators. More specifically, in FIG. 1 the plasma chamber 100 is schematically shown as having an upper electrode 105, lower electrode 110, and plasma 120 generated in between the two electrodes. As is known, electrode 105 is generally embedded in the chamber's ceiling, while electrode 110 is generally embedded in the lower cathode assembly upon which the work piece, such as a semiconductor wafer, is placed. As also shown in FIG. 1, a bias RF power supplier 125 provides RF power to the chamber 100 via match circuit 140. The RF bias is at frequency f1, generally 2 MHz or 13 MHz (more precisely, 13.56 MHz), and is generally applied to the lower electrode 110. FIG. 1 also shows two RF source power suppliers 130 and 135, operating at frequencies f2 and f3, respectively. For example, f2 may be set at 27 MHz, while f3 at 60 MHz. The source power suppliers 130 and 135 deliver power to chamber 100 via match networks 145 and 150, respectively. The source power may be applied to the lower electrode 110 or the top electrode 105. Notably, in all of the Figures the output of the match networks is illustrated as combined into a single arrow leading to the chamber. This is used as a symbolic representation intended to encompass any coupling of the matching networks to the plasma, whether via the lower cathode, via an electrode in the ceiling, an inductive coupling coil, etc. For example, the bias power may be coupled via the lower cathode, while the source power via an electrode in the showerhead or an inductive coil. Conversely, the bias and source power may be coupled via the lower cathode.

FIG. 2 is a schematic illustration of another multiple frequency plasma chamber arrangement, having two switchable RF bias power and one source RF power coupled to a match network. In FIG. 2, two RF bias power suppliers 225 and 255 provide switchable f1 and f2 RF bias power to the chamber 200 via switch 232 that is coupled to match circuits 240 and 245, respectively. The RF bias is at frequency f1, generally 2 MHz or 2.2 MHz, while the RF bias frequency f2 is generally 13 MHz (more precisely, 13.56 MHz). Both RF bias are generally applied to the lower electrode 210. FIG. 2 also shows a source RF power supplier 235, operating at frequency f3, for example, 27 MHz, 60 MHz, 100 MHz, etc. The source power 235 is delivered to chamber 200 via match network 250 and is applied to the lower electrode 210. The source power is used to control the plasma density, i.e., plasma ion dissociation.

The arrangement of FIG. 2 enables superimposed application of either f1/f3 or f2/f3 frequencies to the chamber. For example, f1 can be 400 KHz to 5 MHz; f2 can be 10 MHz to 20 MHz, but normally less than 15 MHz; and f3 can be 27 MHz to 100 MHz or higher. In one particular example, f1 is 2 MHz, f2 is 13.56 MHz, and f3 is 60 MHz. Such an arrangement makes it very easy to run recipes that require switching between low and high frequency bias power in mid processing.

As can be seen in FIG. 2, switch 232 has one input and two selectable outputs. The input is coupled to both RF bias power suppliers 225 and 255. One output is connected to matching circuit 140, while the other to matching circuit 245. Controller 262 operates the switch such that when RF bias power supplier 225 is operational and provide its output to switch 232, the controller directs the switch to connect to output for matching circuit 240, while when RF bias power supplier 255 is operational, the controller directs the switch to connect to output for matching circuit 245. Notably, in this system a single switch is used to connect one of two frequencies to one of two matching circuits. The switch may be an RF power vacuum relay or a PIN diode.

As can be understood from the above examples, a matching network is required for each power supplier, depending on its output frequency. This necessitates multiple matching circuits, which increases the complexity and cost of the system. While from the cost perspective it would be preferable to use a single matching network for multiple frequencies, such an arrangement would negatively affect coupling efficiency.

### SUMMARY OF THE INVENTION

The following summary of the invention is intended to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

The invention provides a single matching network adapted to input at least two frequencies, which is used to selectively provide an RF power match at any one of the two frequencies to a plasma load. The single matching network includes an input terminal connected to a multi-frequency input and an output terminal connected to the plasma load, a capacitor and an inductor connected in series with each other are provided between the input terminal and the output terminal to form a branch, wherein the capacitance value of the capacitor is C₀, the inductance value of the inductor is L₀, and wherein the capacitance value C₀ and the inductance value L₀ satisfy the following relations:

jω₁L₀+1/jω₁C₀=jy1

jω₂L₀+1/jω₂C₀=jy2

wherein ω₁=2πf1, ω₂=2πf2, the f1 and f2 are respectively the first and second frequencies, y1 is the impedance required for the branch when achieving a matching state at frequency f1, and y2 is the impedance required for the branch when achieving a matching state at frequency f2.

The matching network is an L-type, T-type, or π-type network, or any combination and variation of the preceding types.

The input terminal of the single matching network is connected with a single RF power supply device, and the single RF power supply device selectively outputs one of the frequencies f1 and f2 within a certain time period.

The plasma load is a plasma process chamber.

The plasma process chamber includes an upper electrode and a lower electrode, and the output terminal of the single matching network is connected with the upper electrode or the lower electrode.

The matching network also includes a variable element connected between the branch and the ground.

The variable element is a variable capacitor or a variable inductor or the combination thereof.

The invention also provides an RF power source system for switchingly coupling one of at least two frequencies f1 and f2 to an electrode of a plasma process chamber, and the RF power source system includes:

an RF power source device for selectively output one of the frequencies f1 and f2;

a matching network having an input terminal connected to the RF power source device and an output terminal connected to the electrode, wherein the matching network includes a capacitor with the capacitance value of C₀ and an inductor with the inductance value of L₀, and the capacitor and the inductor are connected in series with each other to form a branch; and

wherein the capacitance value C₀ and the inductance value L₀ satisfy the following relations:

jω₁L₀+1/jω₁C₀=jy1

jω₂L₀+1/jω₂C₀=jy2

wherein, ω₁=2πf1, ω₂=2πf2, the f1 and f2 are respectively the first and second frequencies, y1 is the impedance required for the branch when achieving a matching state at the frequency f1, and y2 is the impedance required for the branch when achieving a matching state at the frequency f2.

The matching network is an L-type, T-type, or π-type network, or any combination and variation of the preceding types.

The electrode is an upper electrode or a lower electrode of the plasma process chamber.

The RF power source system also includes a variable element connected between the branch and the ground.

Furthermore, the invention also provides a method of constructing a matching network, wherein the matching network is adapted to couple RF energy from an RF power source device to a plasma load, and the RF power source device selectively provides a power output working at the frequency f1 or f2. The method includes the following steps:

selecting a capacitor and an inductor in the matching network according to the following expressions, wherein the capacitor and the inductor are connected in series with each other to form a branch, the capacitance value of the capacitor is C₀, and the inductance value of the inductor is L₀:

jω₁L₀+1/jω₁C₀=jy1

jω₂L₀+1/jω₂C₀=jy2

wherein, ω₁=2πf1, ω₂=2πf2, the f1 and f2 are respectively the first and second frequencies, y1 is the impedance required for the branch when achieving a matching state at the frequency f1, and y2 is the impedance required for the branch when achieving a matching state at the frequency f2; and

connecting the capacitor and the inductor in series to obtain the matching network, and connecting the matching network in series between the RF power source device and the plasma load.

The matching network is an L-type, T-type, or π-type network, or any combination and variation of the preceding types.

Furthermore, the invention also provides a single matching network adapted to input at least two frequencies, for selectively providing an RF power match at any one of the two frequencies to a plasma load. The single matching network includes an input terminal connected to a multi-frequency input and an output terminal connected to the plasma load, a capacitor and an inductor connected in parallel with each other are provided between the input terminal and the output terminal to form a branch, the capacitance value of the capacitor is C₄, and the inductance value of the inductor is L₄, wherein the capacitance value C₄ and the inductance value L₄ satisfy the following relations:

1/jω₁L₄+jω1C₄=1/jy1

1/jω₂L₄+jω₂C₄=1/jy2

wherein, ω₁=2πf1, ω₂=2πf2, the f1 and f2 are respectively the two frequencies, y1 is the impedance required for the branch when achieving a matching state at the frequency f1, and y2 is the impedance required for the branch when achieving a matching state at the frequency f2.

The matching network is an L-type, T-type, or π-type network, or any combination and variation of the preceding types.

The input terminal of the single matching network is connected with a single RF power supply device, and the single RF power supply device selectively outputs one of the frequencies f1 and f2 within a certain time period.

The plasma load is a plasma process chamber.

The plasma process chamber includes an upper electrode and a lower electrode, and the output terminal of the single matching network is connected with the upper electrode or the lower electrode.

Furthermore, the invention also provides an RF power source system for switchingly coupling one of at least two frequencies f1 and f2 to a electrode of a plasma process chamber, and the RF power source system includes:

an RF power source device for selectively outputting one of the frequencies f1 and f2;

a matching network having an input terminal connected to the RF power source device and an output terminal connected to the electrode, wherein the matching network includes a capacitor with the capacitance value C₄ and an inductor with the inductance value L₄, and the capacitor and the inductor are connected in parallel with each other to form a branch; and

the capacitance value C₄ and the inductance value L₄ satisfy the following relations:

1/jω₁L₄+jω₁C₄=1/jy1

1/jω₂L₄+jω₂C₄=1/jy2

wherein, ω₁=2πf1, ω₂=2πf2, the f1 and f2 are respectively the two frequencies, y1 is the impedance required for the branch when achieving a matching state at the frequency f1, and y2 is the impedance required for the branch when achieving a matching state at the frequency f2.

The matching network is an L-type, T-type, or π-type network, or any combination and variation of the preceding types.

The electrode is an upper electrode or a lower electrode of the plasma process chamber.

Furthermore, the invention also provides a method of constructing a matching network, wherein the matching network is adapted to couple RF energy from an RF power source device to a plasma load, and the RF power source device selectively provides a power output working at the frequency f1 or f2. The method includes the following steps:

selecting a capacitor and an inductor in the matching network according to the following expressions, wherein the capacitor and the inductor are connected in parallel with each other to form a branch, the capacitance value of the capacitor is C₄, and the inductance value of the inductor is L₄:

1/jω₁L₄+jω₁C₄=1/jy1

1/jω₂L₄+jω₂C₄=1/jy2

wherein, ω₁=2πf1, ω₂=2πf2, the f1 and f2 are respectively the two frequencies, y1 is the impedance required for the branch when achieving a matching state at the frequency f1, and y2 is the impedance required for the branch when achieving a matching state at the frequency f2; and connecting the capacitor and the inductor in parallel to obtain the matching network, and connecting the matching network in series between the RF power source device and the plasma load.

The matching network is an L-type, T-type, or π-type network, or any combination and variation of the preceding types.

The method also includes connecting a variable parallel capacitor or a variable parallel inductor between the ground and the matching network.

The frequency f1 or f2 is selected from one of the following frequencies: 2 MHz, 13.56 MHz, 27 MHz, 60 MHz, 100 MHz and 120 MHz.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 is a schematic illustration of a multi-frequency plasma process chamber in the prior art, wherein the plasma process chamber has one RF bias power generator and two RF source power generators.

FIG. 2 is a schematic illustration of a multi-frequency plasma process chamber in the prior art, wherein the plasma process chamber has one RF source power generator and one switchable RF bias power generator.

FIG. 3 is a schematic illustration of a plasma process chamber according to a specific embodiment of the invention, wherein a single matching network HF1 is adapted to provide an RF match to any one of the switchable RF source powers.

FIG. 4 is a Smith Chart showing the formation of the match at a first frequency (60 MHz).

FIG. 5 is a Smith Chart showing the formation of the match at a second frequency (120 MHz).

FIG. 6 shows a single matching network capable of matching the first frequency (60 MHz) and the second frequency (120 MHz) according to the present invention, which is an L-type matching network.

FIG. 7 shows a specific embodiment of the invention, wherein a single matching network LF1 is adapted to match any one of the switchable bias frequencies, and the other two matching networks HF1 and HF2 are adapted to match any one of the switchable source frequencies.

FIG. 8 shows another specific embodiment of a single matching network capable of matching the frequency f1 or f2 according to the present invention, wherein the single matching network is a T-type matching network.

FIG. 9 shows another specific embodiment of a single matching network capable of matching the frequency f1 or f2 according to the present invention, wherein the single matching network is a π-type matching network.

FIG. 10 shows another specific embodiment of a single matching network capable of matching frequency f1 or f2 according to the present invention, wherein the single matching network is an L-type matching network, and wherein the capacitor and the inductor are connected in parallel.

FIG. 11 shows another specific embodiment of a single matching network capable of matching frequency f1 or f2 according to the present invention, wherein the single matching network is a T-type matching network, and wherein the capacitors and the inductors are connected in parallel.

FIG. 12 shows another specific embodiment of a single matching network capable of matching frequency f1 or f2 according to the present invention, wherein the single matching network is a π-type matching network, wherein the capacitor and the inductor are connected in parallel.

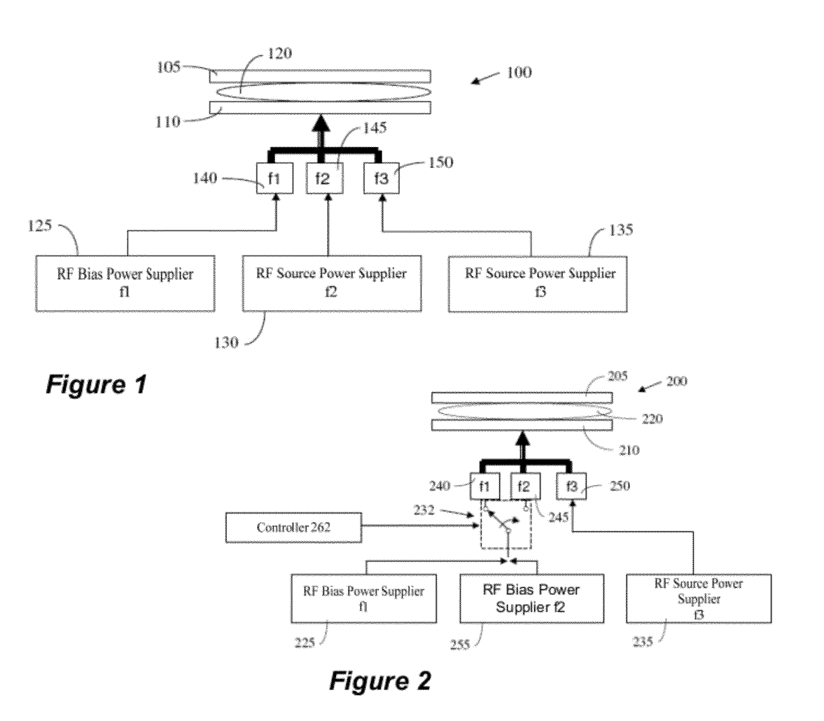

### DETAILED DESCRIPTION

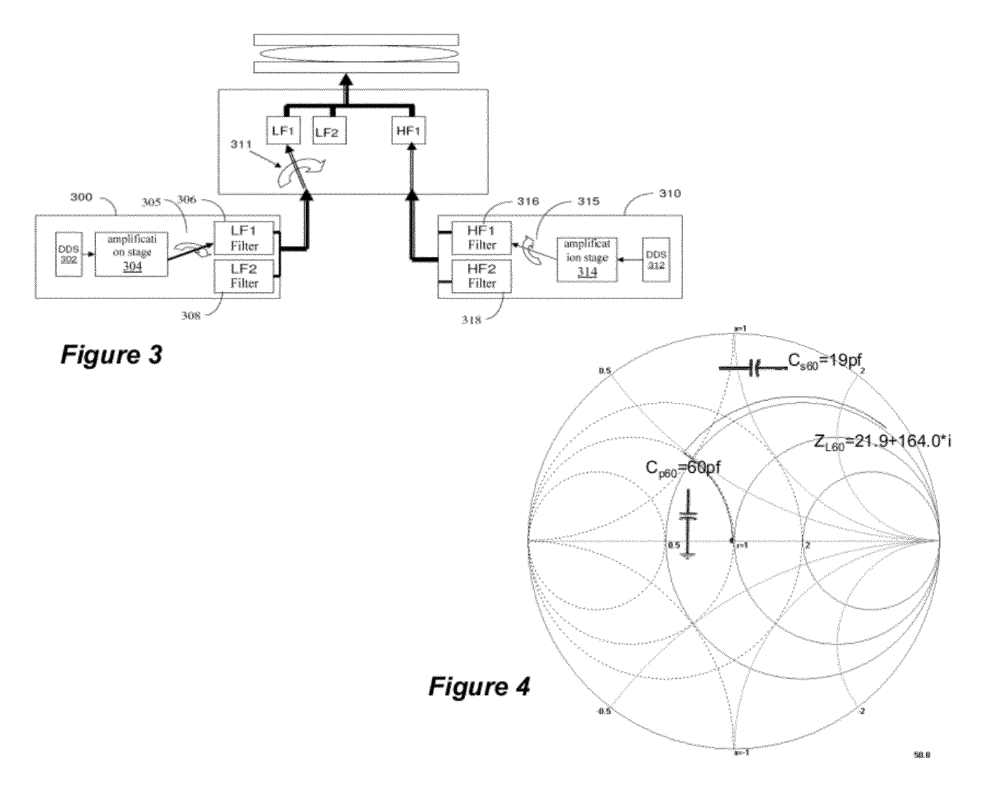

FIG. 3 shows a schematic view of a plasma process chamber according to a specific embodiment of the invention, wherein a single matching network HF1 is adapted to provide an RF match to any one of the switchable RF source powers. As shown in FIG. 3, the plasma process chamber has switchable RF bias powers and switchable RF source powers. In this embodiment, the frequency of the first RF bias power is set to 0.5-10 MHz, and the frequency of the second RF bias power is set to 10-30 MHz. Also, the frequency of the first RF source power is set to 40-100 MHz, for example 60 MHz; and the frequency of the second RF source power is set to 80-200 MHz, for example 120 MHz. Such plasma process chamber can realize better control of the plasma density and the plasma energy so as to increase the adaptability. The left part of FIG. 3 shows an element 300 (i.e. the low frequency part) for providing a number of switchable RF bias powers, and the right part of FIG. 3 shows an element 310 (i.e. the high frequency part) for providing a number of switchable RF source powers. The bold arrow in FIG. 3 schematically indicates that the RF bias powers and the RF source powers are coupled to the plasma process chamber in any conventional manners, wherein the manners include capacitive coupling, inductive coupling, Helicon, etc.

In this embodiment, a single RF power supply device (300 for bias and 310 for source) is used to generate one of several available frequencies, in this example one of two available frequencies. It should be appreciated that while various design schemes can be used to construct such RF power supply device to generate a plurality of available frequencies, the switchable RF bias power or low frequency power generator 300 shown herein includes a direct digital frequency synthesizer (DDS) 302 which provides the RF signal at a selected one of the available frequencies. The signal is then amplified by amplification stage 304, using a wide band amplifier or two narrow band amplifiers, depending on the design choice. The output of the amplification stage 304 is coupled to switch 305, which directs the signal either to low frequency filter 306 or to low frequency filter 308, depending on the frequency output by the DDS 302. The output of generator 300 is applied to the input of switch 311, which is switchably coupled to either of matching networks LF1 or LF2. In this configuration, matching network LF1 is optimized to deliver power at one of the two selectable frequencies, while matching network LF2 is optimized to deliver power at the other frequency. The output from one of the matching networks is applied to the chamber.

In this embodiment, the RF source power or high frequency power generator 310 is adapted to generate one of several available frequencies. As an embodiment, the RF source power generator 310 can be the “mirror image” of the preceding generator 300, which includes a direct digital frequency synthesizer (DDS) 312 for providing an RF signal at a frequency selected from one of available frequencies. Then the RF signal is amplified through an amplification stage 314 by one wide band amplifier or two narrow band amplifiers, depending on the design choice. The output terminal of the amplification stage 314 is connected to the switch 315, and the switch 315 connects the signal to a high frequency filter (filter HF1) 316 or a high frequency filter (filter HF2) 318 based on the frequency output of the DDS 312. The output of the power generator 310 is connected to a single matching network HF1, regardless of the frequency. The output of the matching network HF1 is applied to the plasma process chamber.

It should be understood that, although FIG. 3 shows that the bias frequency part has two matching networks LF1 and LF2, and the source frequency part has only one matching network HF1, these are only used as an example to highlight the features of the invention. That is to say, the specific structure arrangement described above helps to highlight the difference between the use of two matching network and the use of a single matching network. However, in practical application, the bias power part can be arranged similar to the source power part, i.e. the bias power part also can be arranged to have only one single matching network according to the spirits of the invention. Also, according to the spirits of the invention, it is possible to construct a single matching network working for the switchable bias powers and only use one single source power. Conversely, one can use a matching network constructed according to the invention to provide switchable source power, while only single bias power is used.

As shown in FIG. 3, in this embodiment a single matching network HF1 is provided for both high frequencies RF source power. According to features of the invention, the single match network HF1 is designed so as to enable efficient energy coupling for either of the switchable frequencies. The following is an explanation of how such a match network HF1 can be designed.

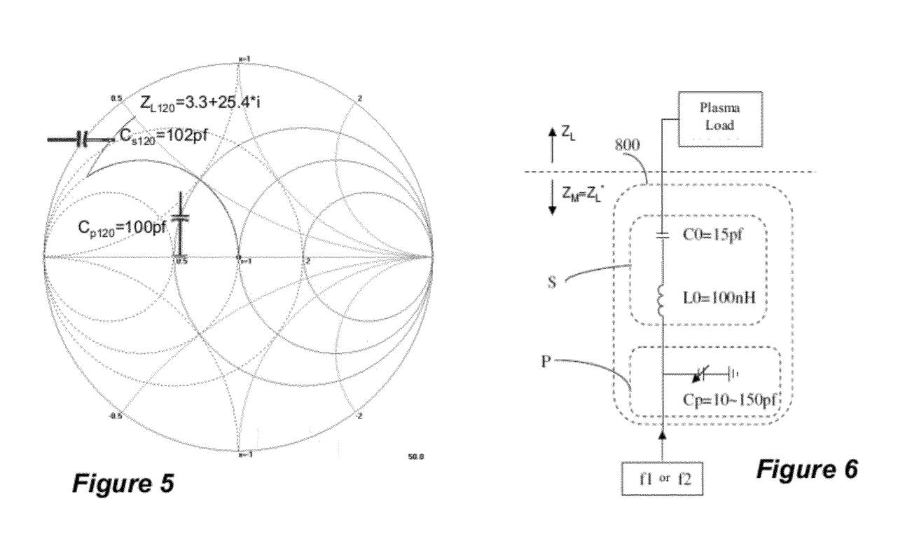

Assuming that the target frequencies are f1 (such as 60 MHz) and f2 (such as 120 MHz), and referring to FIG. 4 and FIG. 5, FIG. 4 is a Smith Chart which shows the formation of a match at the target frequency f1 (60 MHz); FIG. 5 is a Smith Chart showing the formation of a match at the target frequency f2 (120 MHz). In the case of frequency fl, the single matching network HF1 has a series branch S and a parallel branch P (as shown in FIG. 6), wherein the target impedance of the series branch S is j*y₁; and in the case of frequency f2, the single matching network HF1 has a series branch S and a parallel branch P (as shown in FIG. 6), wherein the target impedance of the series branch S is j*y₂. As an embodiment, the series branch S of the single matching network HF1 includes a capacitor element and an inductor element connected in series with each other for matching the power, where the capacitance value and inductance value are C₀ and L₀ respectively. To satisfy the impedance matching requirements at the frequencies f1 and f2, the values of C₀ and L₀ should be set to satisfy the following expressions:

jω₁L₀+1/jω₁C₀=jy₁,

jω₂L₀+1/jω₂C₀=jy₂,

wherein, ω₁=2πf1, ω₂=2πf2.

To illustrate how one may set the parameters of a single match network to operate for two different frequencies f1 and f2, consider again the high frequency part of the embodiment of FIG. 3. Assume that the target frequencies are f1=60 MHz and f2=120 MHz. In the case of frequency f1, the single matching network HF1 has a series branch S and a parallel branch P, wherein the target impedance of the series branch S is j*y₁; and in the case of frequency f2, the single matching network HF1 has a series branch S and a parallel branch P, wherein the target impedance of the series branch S is j*y₂. It is known from the specific embodiment shown in FIG. 3 that C₀ and L₀ should satisfy the following relations:

jω₁L₀+1/jω₁C₀=jy₁,

jω₂L₀+1/jω₂C₀=jy₂,

wherein ω₁=2πf1, ω₂=2πf2.

Therefore, the value Cₒ and Lₒ are required to be determined so that the above-mentioned single matching network HF1 part can satisfy the matching conditions of f1 and f2. Referring to FIG. 4 again, it is assumed that the load impedance is Z_{L60}=21.9+164.0*i when the frequency is 60 MHz. As an embodiment, assuming that the single matching network HF1 is designed as an L-type matching network, it is needed that the capacitor in the series branch S is Cₛ₆₀=19 pf and the capacitor in the parallel branch P is Cₚ₆₀=60 pf. As a result, y1=1/ω₁Cₛ₆₀=−139.6 Ω. Referring to FIG. 5 again, it is assumed that the load impedance Z_{L120}=3.3+25.4*i when the frequency is 120 MHz. As a result, in the L-type match network, it is needed that the capacitor in the series branch S is Cₛ₁₂₀=102 pf and the capacitor in the parallel branch P is Cₚ₁₂₀=100 pf, so y₂=1/ω₂Cₛ₁₂₀=−13.0 Ω. Solving the following equation group:

jω₁L₀+1/jω₁C₀=jy₁=−139.6*jΩ,

jω₂L₀+1/jω₂C₀=jy₂==13.0*jΩ,

wherein ω₁=2πf1, ω₂=2πf2,

obtaining L₀=100 nH, C₀=15 pf.

Therefore, a single matching network 800 shown in FIG. 6 can be constructed by the method of the invention, which is an L-type network and wherein an inductor with the inductance value L₀ of 100 nH and a capacitor with the capacitance value C₀ of 15 pf are connected in series in the series branch S. A variable capacitor Cp is connected in the parallel branch P, which is set to 60 pf when the frequency is 60 MHz, and to 100 pf when the frequency is 120 MHz. In this way, a single matching network shown in FIG. 6 can be used for a system with two switchable frequencies.

The variable capacitor Cp shown in FIG. 6 is a variable or adjustable element, and is connected between the series branch S and the ground, and its value is adjustable so that the single matching network 800 can satisfy the matching requirements at different frequency f1 or f2. There can be a number of variations for the connection relation of the variable capacitor Cp, for example, the variable capacitor Cp can be connected between the ground and one of the following positions: the input terminal of the matching network 800, the intermediate point between the capacitor C₀ and the inductor L₀, or the output terminal of the matching network 800. Further, since the single matching network of the invention can be of an L-type, a π-type, or a T-type, or a combination of any two types of the preceding types or a variation of the combination (which will be described in detail hereinafter), the connection of the variable capacitor Cp to one end of the series branch S can also have a corresponding connection manner, and the connection should be well known by those skilled in the art, thus it will not be described in detail herein. It should be understood that the variable element can be a variable capacitor, a variable inductor, or the combination of the variable capacitor and the variable inductor.

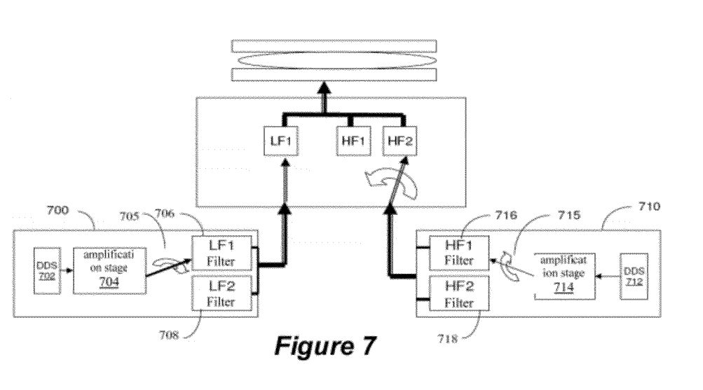

As described above, the invention is not limited to the specific embodiment shown in FIG. 3. Those skilled in the art can design a single matching network for providing an RF match to any switchable frequency according to the spirits of the invention. FIG. 7 shows another specific embodiment in which a plasma process chamber includes a switchable RF bias power and a switchable RF source power. The construction of the RF source power part is similar to the bias power part shown in FIG. 3. That is to say, the RF source power part has two matching networks HF1 and HF2, and each RF frequency matches with a corresponding matching network. However, the RF bias power part or the low frequency power part in FIG. 3 is arranged according to the method of the invention. A switchable power generator 700 is connected with a single matching network LF1. The power generator 700 includes a direct digital frequency synthesizer (DDS) for providing an RF signal, and the frequency of the RF signal is selected from a number of available frequencies. Then, according to the design, the RF signal is amplified through an amplification stage 704 by one wide band amplifier or two narrow band amplifiers. The output terminal of the amplification stage 704 is connected to a switch 705, and the switch 705 connects the RF signal to either a low frequency filter (filter LF1) 706 or a low frequency filter (filter LF2) 708 based on the frequency output of the direct digital frequency synthesizer (DDS). The output terminal of the power generator 700 is connected with a single matching network LF1. The selection of the parameters of the capacitor and inductor element of the single matching network LF1 is the same as the preceding selection of the corresponding parameter values in the high frequency part. The output terminal of the single matching network LF1 is connected to the plasma process chamber.

As described above, the single matching network of the invention shown in FIG. 6 is an L-type network, which includes a capacitor C₀ and an inductor L₀ connected in series with each other. It should be appreciated that the single matching network of the invention can also be various equivalent variations of the matching network shown in FIG. 6, for example the L-type shown in FIG. 6 can be varied to π-type or T-type, or a combination of any two types of the preceding L-type, π-type and T-type, or a variation of the combination.

For example, FIG. 8 shows another embodiment of the single matching network of the invention, wherein the single matching network 820 is a T-type matching network, which is used for providing an impedance match to any one of the switchable bias frequencies f1 and f2. In this matching network 820, the values of the inductor L and the capacitor C should satisfy the impedance matching requirements at two specific frequencies f1 and f2, that is to say, the impedance of the series branch S1 is y_{f1}_{_{—}}₁ and the impedance of the series branch S2 is y_{f1}_{_{—}}₂ when the frequency is f1, and the impedance of the series branch S1 is y_{f2}_{_{—}}₁ and the impedance of the series branch S2 is y_{f2}_{_{—}}₂ when the frequency is f2. The setting process of such matching network is similar to the preceding setting process of the L-type network shown in FIG. 6. If the frequency is fl, the load impedance is Z_{f1}. The T-type matching network needs that the inductor in the series branch Si is L_{s1f1}, the inductor in the series branch S2 is L_{s2f1}, and the capacitor in the parallel branch P is C_{pf1}. Then, y_{f1}_{_{—}}₁=ω₁L_{s1f1}, y_{f1}_{_{—}}₂=ω₁¹L_{s2f1}. When the frequency is f2, the load impedance is Z_{f2}. The T-type matching network needs that the inductor in the series branch S1 is L_{s1f2}, the inductor in the series branch S2 is L_{s2f2}, and the capacitor in the parallel branch P is C_{pf2}. Then, y_{f2}_{_{—}}₁=ω₂L_{s1f2}, y_{f2}_{_{—}}₂=ω₂L_{s2f2}. Solving the following two equation groups:

jω₁L₁+1/jω₁C₁=jy_{f1}_{_{—}}₁

jω₂L₁+1/jω₂C₁=jy_{f2}_{_{—}}₁

and

jω₁L₂+1/jω₁C₂=jy_{f1}_{_{—}}₂

jω₂L₂+1/jω₂C₂=jy_{f2}_{_{—}}₂

wherein, ω₁=2πf1, ω₂=2πf2

then the values of L₁, C₁ in the series branch S1, and the values of L₂, C₂ in the series branch S2 can be obtained.

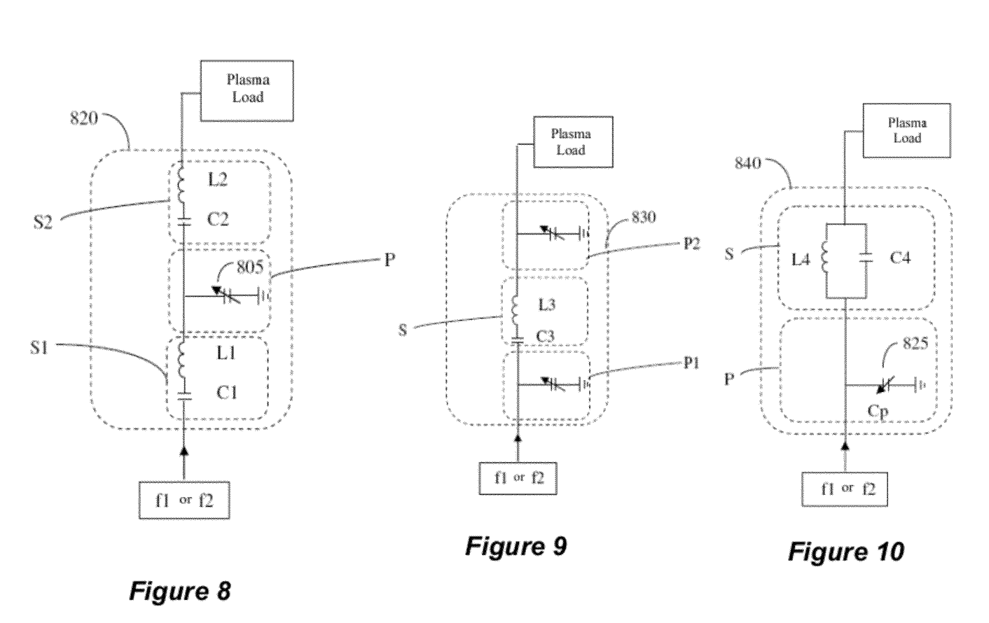

FIG. 9 shows another embodiment of the single matching network according to the invention, wherein the single matching network 830 is a π-type matching network, which is used for providing an impedance match to any one of the switchable frequency f1 or f2. Similarly, if the frequency is f1, the load impedance is Z_{f1}. The π-type matching needs that the inductor in the series branch S is L_{f1}, the capacitor in the parallel branch P1 is Cₚₗ_{—}_{f1}, and the capacitor in the parallel branch P2 is Cₚ₂_{_{—}}_{f1}. Then, y_{f1}=ω₁L_{f1}. If the frequency is f2, the load impedance is Z_{f2}. The π-type matching needs that the inductor in the series branch S is L_{f2}, the capacitor in the parallel branch P1 is Cp₁_{_{—}}_{f2}, and the capacitor in the parallel branch P2 is Cₚ₂_{_{—}}_{f2}. Then, y_{f2}=ω₂L_{f2}. Solving the following equation group:

jω₁L₃+1/jω₁C₃=jy_{f1},

jω₂L₃+1/jω₂C₃=jy_{f2},

wherein, ω₁=2πf1, ω₂=2πf2,

then the values of L3, C3 can be obtained.

FIGS. 10, 11 and 12 show other variations of the embodiment of the single matching network which can match frequency f1 or f2 according to the invention. The difference between these variations and the matching networks shown in preceding FIGS. 6, 8 and 9 is that: the capacitor and the inductor in the matching network shown in FIG. 6, 8, or 9 are connected in series, while the capacitor and the inductor in the matching network shown in FIG. 10, 11, or 12 are connected in parallel.

As shown in FIG. 10, the inductor L₄ and the capacitor C₄ are connected in parallel, and the matching network is of L-type. If the frequency is f1, the load impedance is Z_{f1}. The L-type matching needs that the inductor in the series branch S is Lₙ and the capacitor in the parallel branch P is C_{f1}. Then y_{f1}=ω₁L_{f1}. If the frequency is f2, the load impedance is Z_{f2}. The L-type matching needs that the inductor in the series branch S is L_{f2} and the capacitor in the parallel branch P is C_{f2}. Then y_{f2}=ω₂L_{f2}. The values of the capacitor C₄ and inductor L₄ should be set to satisfy the following expressions:

1/jω₁L₄+jω₁C₄=1/jy_{f1}

1/jω₂L₄+jω₂C₄=1/jy_{f2}

wherein, ω₁=2πf1, ω₂=2πf2,

then the values of L4, C₄ can be obtained.

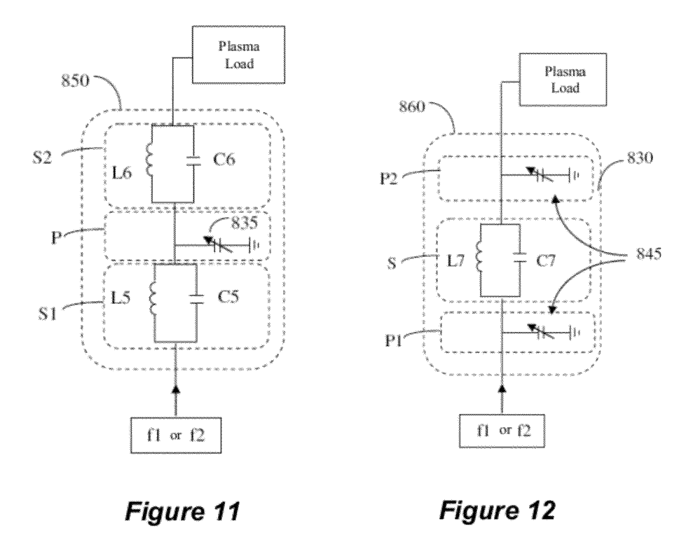

As shown in FIG. 11, the inductor L5 and the capacitor C5 are connected in parallel, the inductor L6 and the capacitor C6 are connected in parallel with each other, and the matching network is of T-type. If the frequency is f1, the load impedance is Z_{f1}. The T-type matching network needs that the inductor in the series branch S1 is L_{s1f1}, the inductor in the series branch S2 is L_{s2f1} and the capacitor in the parallel branch P is C_{pf1}. Then, y_{f1}_{_{—}}₁=ω₁L_{s1f1}, and y_{f1}_{_{—}}₂=ω₁L_{s2f1}. If the frequency is f2, the load impedance is Z_{f2}. The T-type matching needs that the inductor in the series branch S1 is L_{s1f2}, the inductor in the series branch S2 is L_{s2f2}, and the capacitor in the parallel branch P is C_{pf1}. Then, y_{f2}_{_{—}}₁=ω₂L_{s1f2}, and y_{f2}_{_{—}}₂=ω₂L_{s2f2}. The values of the capacitor C₅ and inductor L₅ should be set to satisfy the following expressions:

1/jω₁L₅+jω₁C₅=1/jy_{f1}_{_{—}}₁

1/jω₂L₅+jω₂C₅=1/jy_{f2}_{_{—}}₁

and the values of the capacitor C₆ and inductor L₆ should be set to satisfy the following expressions:

1/jω₁L₆+jω₁C₆=1/jy_{f1}_{_{—}}₂

1/jω₂L₆+jω₂C₆=1/jy_{f2}_{_{—}}₂

Wherein, ω₁=2πf1, ω₂=2πf2,

then the values of L₅, C₅, L₆, and C₆ can be obtained.

As shown in FIG. 12, an inductor L7 and a capacitor C7 are connected in parallel, and the matching network is of π-type. If the frequency is f1, the load impedance is Z_{f1}. The π-type matching needs that the inductor in the series branch S is L_{f1}, the capacitor in the parallel branch P1 is Cₚ₁_{_{—}}_{f1}, and the capacitor in the parallel branch P2 is Cₚ₂_{_{—}}_{f1}. Then, y_{f1}=ω₁L_{f1}. If the frequency is f2, the load impedance is Z_{f2}. The π-type matching needs that the inductor in the series branch S is L_{f2}, the capacitor in the parallel branch P1 is Cₚ₁_{_{—}}_{f2}, and the capacitor in the parallel branch P2 is Cₚ₂_{_{—}}_{f2}. Then, y_{f2}=ω₂L_{f2}. The values of the capacitor C₇ and inductor L₇ should be set to satisfy the following expressions:

1/jω₁L₇+jω₁C₇=1/jy_{f1}

1/jω₂L₇+jω₂C₇=1/jy_{f2}

wherein, ω₁=2πf1, ω₂=2πf2,

then the values of L₇, C₇ can be obtained.

Furthermore, according to the spirits and the essence of the invention, the invention also provides a method of constructing a matching network adapted to couple RF energy from an RF power source device to a plasma load, wherein the RF power source device selectively provides the power output working at frequency f1 or f2, and the method includes the following steps:

selecting a capacitor and an inductor in the matching network according to the following expressions, wherein the capacitor and the inductor are connected in series with each other to form a branch, the capacitance value of the capacitor is C₀, the inductance value of the inductor is L₀:

jω₁L₀+1/jω₁C₀jy1

jω₂L₀+1/jω₂C₀jy2

wherein, ω₁=2πf1, ω₂=2πf2, the f1 and f2 are respectively the two frequencies, y1 is the impedance required for the branch when achieving a matching state at frequency f1, and y2 is the impedance required for the branch when achieving a matching state at frequency f2; and

connecting the capacitor and the inductor in series to obtain the matching network, and connecting the matching network in series between the RF power source device and the plasma load.

The matching network may be constructed as an L-type, T-type, or π-type network, or any combination and variation of the preceding type network.

In the invention, in all the embodiments described in the present disclosure, the frequency f1 or f2 can be any frequency, and preferably, it can be selected from one of the following frequencies: 2 MHz, 13.56 MHz, 27 MHz, 60 MHz, 100 MHz and 120 MHz.

Furthermore, the preceding method can also include connecting a variable element between the branch and the ground to satisfy the requirement of the matching network achieving a match at different frequency f1 or f2. The variable element can be a variable capacitor, a variable inductor, or the combination of variable capacitor and variable inductor.

Furthermore, according to the spirits and the essence of the invention, the invention also provides a method of constructing a matching network adapted to coupling RF energy from an RF power source device to a plasma load, wherein the RF power source device selectively provides the power output at frequency fl or f2, and the method includes the following steps:

selecting a capacitor and an inductor in the matching network according to the following expressions, wherein the capacitor and the inductor are connected in parallel with each other to form a branch, the capacitance value of the capacitor is C₄, the inductance value of the inductor is L₄:

1/jω₁L₄+jω₁C₄=1/jy1,

1/jω₂L₄+jω₂C₄=1/jy2,

wherein, ω₁=2πf1, ω₂=2πf2, the f1 and f2 are respectively the two frequencies, y1 is the impedance required for the branch when achieving the match state at frequency f1, and y2 is the impedance required for the branch when achieving the match state at frequency f2; and

connecting the capacitor and the inductor in parallel to obtain the matching network, and connecting the matching network in series between the RF power source device and the plasma load.

The matching network can be constructed as an L-type, T-type, or π-type network, or any combination and variation of the preceding types.

The frequency f1 or f2 can be any frequency, and preferably, it can be selected from one of the following frequencies: 2 MHz, 13.56 MHz, 27 MHz, 60 MHz, 100 MHz and 120 MHz.

Furthermore, the preceding method can also include connecting a variable element between the branch and the ground to satisfy the requirement of the matching network achieving a match at different frequency f1 or f2. The variable element can be a variable capacitor, a variable inductor, or the combination of variable capacitors and variable inductors.

Finally, it should be understood that processes and techniques described herein are not inherently related to any particular apparatus and may be implemented by any suitable combination of components. Further, various types of general purpose devices may be used in accordance with the teachings described herein. It may also prove advantageous to construct specialized apparatus to perform the method steps described herein. The present invention has been described in relation to particular examples, which are intended in all respects to be illustrative rather than restrictive. Those skilled in the art will appreciate that many different combinations of hardware, software, and firmware will be suitable for practicing the present invention.

The present invention has been described in relation to particular examples, which are intended in all respects to be illustrative rather than restrictive. Those skilled in the art will appreciate that many different combinations of hardware, software, and firmware will be suitable for practicing the present invention. Moreover, other implementations of the invention will be apparent to those skilled in the art from consideration of the specification and practice of the invention disclosed herein. Various aspects and/or components of the described embodiments may be used singly or in any combination in the plasma chamber arts. It is intended that the specification and examples be considered as exemplary only, with a true scope and spirit of the invention being indicated by the following claims.

1. A single matching network adapted to input at least two frequencies, which is used to selectively provide an RF power match at any one of the at least two frequencies to a plasma load, the single matching network comprising an input terminal connected to a multi-frequency input and an output terminal connected to the plasma load, a capacitor and an inductor connected in series with each other being provided between the input terminal and the output terminal to form a branch, the capacitance value of the capacitor being C₀, the inductance value of the inductor being L₀, wherein the capacitance value C₀ and the capacitance value L₀ satisfy the following relations:
jω₁L₀+1/jω₁C₀=jy1
jω₂L₀+1/jω₂C₀=jy2
wherein ω₁=2πf1, ω₂=2πf2, the f1 and f2 are respectively the two frequencies, y1 is the impedance required for the branch when achieving a matching state at frequency f1, and y2 is the impedance required for the branch when achieving a matching state at frequency f2.

2. The single matching network according to claim 1, wherein the matching network is an L-type, T-type, or π-type network, or any combination and variation of the preceding types.

3. The single matching network according to claim 1, wherein the input terminal of the single matching network is connected with a single RF power supply device, and the single RF power supply device selectively outputs one of the frequencies f1 and f2 within a certain time period.

4. The single matching network according to claim 1, wherein the plasma load is a plasma process chamber.

5. The single matching network according to claim 4, wherein the plasma process chamber comprises an upper electrode and a lower electrode, and the output terminal of the single matching network is connected with the upper electrode or the lower electrode.

6. The single matching network according to claim 1, further comprising a variable element connected between the branch and the ground.

7. The single matching network according to claim 6, wherein the variable element is a variable capacitor, a variable inductor or the combination thereof.

8. An RF power source system for switchingly coupling one of at least two frequencies f1 and f2 to an electrode of a plasma process chamber, the RF power source system comprising:
an RF power source device for selectively outputting one of the frequencies f1 and f2;
a matching network having an input terminal connected to the RF power source device and an output terminal connected to the electrode, wherein the matching network comprises a capacitor with the capacitance value of C₀ and an inductor with the inductance value of L₀, and the capacitor and the inductor are connected in series with each other to form a branch; and
wherein, the capacitance value C₀ and the inductance value L₀ satisfy the following relations:
jω₁L₀+1/jω₁C₀=jy1
jω₂L₀+1/jω₂C₀=jy2
wherein, ω₁=2πf1, ω₂=2πf2, the f1 and f2 are respectively the two frequencies, y1 is the impedance required for the branch when achieving a matching state at frequency f1, and y2 is the impedance required for the branch when achieving a matching state at frequency f2.

9. The RF power source system according to claim 8, wherein the matching network is an L-type, T-type, or π-type network, or any combination and variation of the preceding types.

10. The RF power source system according to claim 8, wherein the electrode is an upper electrode or a lower electrode of the plasma process chamber.

11. The RF power source system according to claim 8, further comprising a variable element connected between the branch and the ground.

12. A method of constructing a matching network, wherein the matching network is adapted to couple RF energy from an RF power source device to a plasma load, and the RF power source device selectively provides a power output working at a frequency fl or f2, the method including the following steps:
selecting a capacitor and an inductor in the matching network according to the following expressions, wherein the capacitor and the inductor are connected in series with each other to form a branch, the capacitance value of the capacitor is C₀, and the inductance value of the inductor is L₀:
jω₁L₀+1/jω₁C₀=jy1
jω₂L₀+1/jω₂C₀=jy2
wherein, ω₁=2πf1, ω₂=2πf2, the f1 and f2 are two frequencies, y1 is the impedance required for the branch when achieving a matching state at the frequency f1, and y2 is the impedance required for the branch when achieving a matching state at the frequency f2; and
connecting the capacitor and the inductor in series to obtain the matching network, and connecting the matching network in series between the RF power source device and the plasma load.

13. The method according to claim 12, wherein the matching network is an L-type, T-type, or π-type network, or any combination and variation of the preceding types.

14. The method according to claim 12, further comprising connecting a variable element between the branch and the ground.

15. A single matching network adapted to input at least two frequencies, which is used to selectively provide an RF power match at any one of the two frequencies to a plasma load, the single matching network comprising an input terminal connected to a multi-frequency input and an output terminal connected to the plasma load, a capacitor and an inductor connected in parallel with each other being provided between the input terminal and the output terminal to form a branch, the capacitance value of the capacitor being C₄, the inductance value of the inductor being L₄, wherein the capacitance value C₄ and the inductance value L₄ satisfy the following relations:
1/jω₁L₄+jω₁C₄=1/jy1
1/jω₂L₄+jω₂C₄=1/jy2
wherein, ω₁=2πf1, ω₂=2πf2, the f1 and f2 are respectively the two frequencies, y1 is the impedance required for the branch when achieving a matching state at frequency f1, and y2 is the impedance required for the branch when achieving a matching state at frequency f2.

16. The single matching network according to claim 15, wherein the matching network is an L-type, T-type, or π-type network, or any combination and variation of the preceding types.

17. The single matching network according to claim 15, wherein the input terminal of the single matching network is connected with a single RF power supply device, and the single RF power supply device selectively outputs one of the frequencies f1 and f2 within a certain time period.

18. The single matching network according to claim 15, wherein the plasma load is a plasma process chamber.

19. The single matching network according to claim 18, wherein the plasma process chamber comprises an upper electrode and a lower electrode, and the output terminal of the single matching network is connected with the upper electrode or the lower electrode.

20. The single matching network according to claim 15, further comprising a variable element connected between the branch and the ground.

21. An RF power source system for switchingly coupling one of at least two frequencies f1 and f2 to an electrode of a plasma process chamber, the RF power source system comprising:
an RF power source device for selectively outputting one of the frequencies f1 and f2;
a matching network having an input terminal connected to the RF power source device and an output terminal connected to the electrode, wherein the matching network comprises a capacitor with the capacitance value of C₄ and an inductor with the inductance value of L₄, and the capacitor and the inductor are connected in parallel with each other to form a branch; and
the capacitance value C₄ and the inductance value L₄ satisfy the following relations:
1/jω₁L₄+jω₁C₄=1/jy1
1/jω₂L₄+jω₂C₄=1/jy2
wherein, ω₁=2πf1, ω₂=2πf2, the f1 and f2 are respectively the two frequencies, y1 is the impedance required for the branch when achieving a matching state at the frequency f1, and y2 is the impedance required for the branch when achieving a matching state at the frequency f2.

22. The RF power source system according to claim 21, wherein the matching network is an L-type, T-type, or π-type network, or any combination and variation of the preceding types.

23. The RF power source system according to claim 21, wherein the electrode is an upper electrode or a lower electrode of the plasma process chamber.

24. The RF power source system according to claim 21, further comprising a variable element connected between the branch and the ground.

25. A method of constructing a matching network, wherein the matching network is adapted to couple RF energy from an RF power source device to a plasma load, and the RF power source device selectively provides a power output working at the frequency f1 or f2, the method including the following steps:
selecting a capacitor and an inductor in the matching network according to the following expressions, wherein the capacitor and the inductor are connected in parallel with each other to form a branch, the capacitance value of the capacitor is C₄, and the inductance value of the inductor is L₄:
1/jω₁L₄+jω₁C₄=1/jy1
1/jω₂L₄+jω₂C₄=1/jy2
wherein, ω₁=2πf1, ω₂=2πf2, the f1 and f2 are respectively two frequencies, y1 is the impedance required for the branch when achieving a matching state at the frequency f1, and y2 is the impedance required for the branch when achieving a matching state at the frequency f2; and
connecting the capacitor and the inductor in parallel to obtain the matching network, and connecting the matching network in series between the RF power source device and the plasma load.

26. The method according to claim 25, wherein the matching network is an L-type, T-type, or π-type network, or any combination and variation of the preceding types.

27. The method according to claim 25, further comprising connecting a variable parallel capacitor or a variable parallel inductor between the ground and the matching network.

28. The method according to claim 25, wherein the frequency f1 or f2 is selected from one of the following frequencies: 2 MHz, 13.56 MHz, 27 MHz, 60 MHz, 100 MHz and 120 MHz.
